(19) United States
(12) Patent Application Publication
(10) Pub. No.: US 2008/0146012 A1
(43) Pub. Date: Jun. 19, 2008

(54) NOVEL METHOD TO ADJUST WORK FUNCTION BY PLASMA ASSISTED METAL INCORPORATED DIELECTRIC

(75) Inventors: Wenli Lin, Hsinchu City (TW); Yong-Tian Hou, Singapore (SG); Kang-Cheng Lin, Yonghe City (TW); Kuo-Tai Huang, Hsinchu (TW); Tze-Liang Lee, Hsinchu (TW); Mong-Song Liang, Hsin-Chu (TW)

Correspondence Address: HAYNES AND BOONE, LLP, 901 Main Street, Suite 3100, Dallas, TX, 75202, US

(73) Assignee: TAIWAN SEMICONDUCTOR MANUFACTURING COMPANY, LTD., Hsin-Chu (TW)

(21) Appl. No.: 11/695,227

(22) Filed: Apr. 2, 2007

Related U.S. Application Data
(60) Provisional application No. 60/870,154, filed on Dec. 15, 2006.

(51) Int. Cl. H01L 21/3205; H01L 21/31

(52) U.S. Cl. 438/585; 438/785

(57) ABSTRACT

The present disclosure provides a method of fabricating a semiconductor device. The method includes forming a gate dielectric on a substrate; introducing metal dopants into the gate dielectric; annealing the gate dielectric; and forming a gate electrode on the gate dielectric.

### CROSS-REFERENCE

This application claims the benefit of U.S. Provisional Application 60/870,154 entitled “A Novel Method to Adjust Work Function by Plasma Assisted Metal Incorporated Dielectric,” filed Dec. 15, 2006, herein incorporated by reference in its entirety.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing have been needed.

In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

During the scaling trend, various materials are implemented for gate electrode and gate dielectric for MOS or CMOS devices. To adjust work function of a transistor, traditional approach is introducing additional material into gate electrode. For a polysilicon gate, the work function is adjusted by ion implantation of dopant species (such as As, P, or B) into the polysilicon gate. However, this approach is incompatible with high-K dielectric film due to fermi-level pinning. For a fully silicidation (FUSI) gate, the work function is adjusted by change of silicide phase (such as NiSi→Ni2Si . . . etc) through ion implantation of dopant species such as Yb, Al, Sb, Pt . . . etc. Unfortunately, capability of work function tuning through implanted silicide is not enough. Furthermore, the process is complicated, not cost effective, and low yield.

Accordingly, what is needed is a method for properly and effectively tuning the work function of a gate.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flow chart illustrating one embodiment of a method for fabricating an transistor gate.

FIGS. 2-3 are cross-sectional views of one embodiment of a transistor gate during various fabrication stages using the method of FIG. 1.

FIG. 4 is a diagram of characteristic of gate leakage of metal doped gates in various embodiments.

### DETAILED DESCRIPTION

It is to be understood that the following disclosure provides many different embodiments, or examples, for implementing different features of the invention. Specific examples of components and arrangements are described below to simplify the present disclosure. These are, of course, merely examples and are not intended to be limiting. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

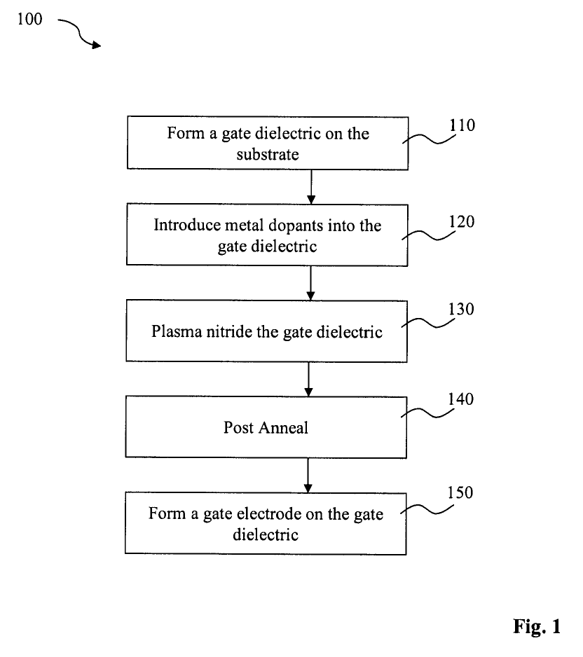

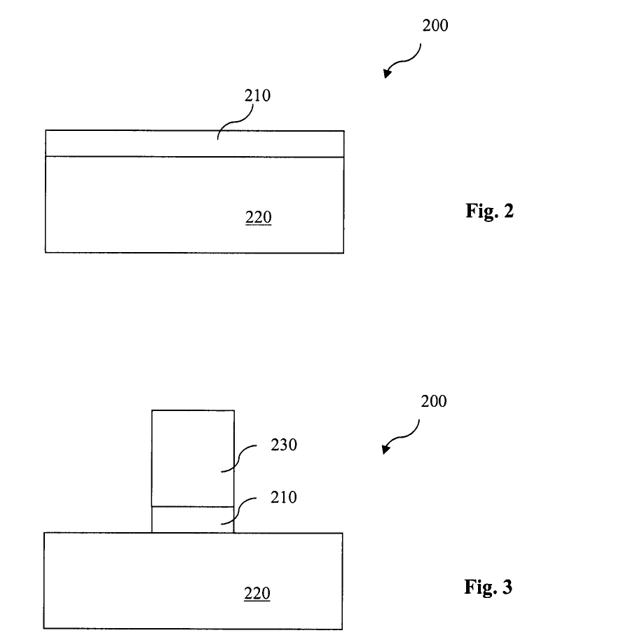

In one embodiment, a flow chart of a method 100 is provided to incorporate metal dopants within a gate dielectric. FIGS. 2 and 3 illustrate sectional views of one embodiment of a semiconductor device 200 with metal dopants incorporated within a gate dielectric during various fabrication stages. The semiconductor device 200 and the method 100 making the same are collectively described with reference to FIGS. 1 to 3.

Referring to FIGS. 1 and 2, the method 100 begins at step 110 by forming a gate dielectric 210 on a substrate 220. The substrate 220 includes silicon. The substrate 220 may alternatively include silicon germanium, gallium arsenic, or other suitable semiconductor materials. The substrate 220 may further include other features such as various doped regions, a buried layer, and/or an epitaxy layer. Furthermore, the substrate 220 may be a semiconductor on insulator such as silicon on insulator (SOI). In other embodiments, the semiconductor substrate may include a doped epi layer, a gradient semiconductor layer, and/or may further include a semiconductor layer overlying another semiconductor layer of a different type such as a silicon layer on a silicon germanium layer. In other examples, a compound semiconductor substrate may include a multilayer silicon structure or a silicon substrate may include a multilayer compound semiconductor structure.

The gate dielectric 210 is disposed on the substrate 220 and configured properly with other electric features (such as source and drain). The gate dielectric 210 has a thickness ranging between about 5 angstrom and about 30 angstrom. The gate dielectric 210 includes silicon oxide. The silicon oxide gate dielectric may be formed using a technique such as thermal oxidation. Other oxidation techniques may be utilized. For example, a rapid thermal process (RTP) may be implemented at oxygen containing ambient to form the gate dielectric 210. The gate dielectric 210 may alternatively or additionally include other suitable dielectric material. Preferably, such material will have relatively high integrity and low current leakage. Examples of such dielectric materials may include silicon oxynitride, or a dielectric with a high dielectric constant (high k). In one embodiment, the silicon oxide gate dielectric may be nitridized to form silicon oxynitride gate dielectric. Examples of a high k dielectric material may include hafnium oxide, zirconium oxide, aluminum oxide, hafnium dioxide-alumina (HfO₂—Al₂O₃) alloy, or combinations thereof. The gate dielectric 210 may include a multilayer structure. In one example, the gate dielectric 210 includes a dielectric stack with a layer of silicon oxide on the substrate and a layer of high k dielectric on the layer of silicon oxide.

As noted above, optionally, a plasma nitridation processing step can be performed on the silicon oxide layer. In one embodiment, the plasma nitridation before metal doping may have two effects. One is to increase dielectric constant of silicon oxide layer and the other is to retard the diffusion of doped metal toward silicon substrate.

Further referring to FIGS. 1 and 2, the method 100 proceeds to step 120 by introducing metal species (or dopants) into the gate dielectric 210. In one embodiment, the metal species may include hafmium (Hf), aluminum (Al), lanthanum (La), or combinations thereof. Other proper metal dopants may be used to dope the gate dielectric. In one example, the metal species include Al, Ga, In, or combinations thereof as dopants to a gate dielectric having Al2O3 or Ga2O3. In another example, the metal species include Hf, La, Sc, Zr, Dy, Er, Lu, or combinations thereof as dopants to a gate dielectric having a high k material gate. In another example, the metal species include Ba, Sr, or combinations thereof as dopants to a gate dielectric for capacitor applications. In another example, the metal species include Y, Ti, V, Nb, Ta, Ce, Pr, Nd, Pm, Sm, Eu, Gd, Tb, Ho, Tm, Yb, or combinations thereof as dopants for other proper gate dielectric. If applicable, various types of metal dopants may be incorporated into the gate dielectric with a proper combination and in separate steps or in a collective processing step. In one embodiment, the metal dopants in the gate dielectric has a concentration from near zero up to about 20 atomic %. In one example, after the metal species were introduced into the silicon oxide gate dielectric layer, the dielectric constant in doped region can be raised from regular-k (3.9-8.0) to medium-k (8.0-15).

Diffusion of metal species into the semiconductor substrate may lead to leakage, mobility degradation and reliability degradation. To prevent metal species from diffusing into substrate, metal species is introduced only within the gate dielectric layer. Preferably, metal species is introduced into the gate dielectric layer extending to a depth of about ¾ of its thickness from the top surface of the gate dielectric.

The metal species may be introduced into the gate dielectric layer by a technique: first forming metal ions using plasma and then incorporating the metal ions into the gate dielectric. In one embodiment, the metal species is introduced into the silicon oxide gate dielectric by ion-metal plasma (IMP) process, to form a metal-doped silicon oxide gate dielectric. In further example, a Centura System developed by Applied Materials may be utilized for IMP processing. In one example, the IMP system includes radio frequency (RF) power ranging between about 100 W and about 3000 W. In another example, the processing duration by the IMP system ranges from about 10 seconds to about 300 seconds. In another example, the IMP system includes a pressure from about 0.01 Torr to about 1 Torr. In a further example, the IMP system includes a processing temperature around room temperature.

Other techniques may be utilized additionally or alternatively to introduce metal species into the gate dielectric such as a silicon oxide gate dielectric. In one example, a plasma ion immersion implantation” (PIII) technique is used for introducing metal species into the gate dielectric. In another example, a traditional ion implantation technique is used to introduce metal species into the silicon oxide layer or other type gate dielectric. Since the gate dielectric layer is very thin, it requires very low implant energy and dose to introduce metal species with the gate dielectric.

Further referring to FIGS. 1 and 2, the method 100 may proceed to step 130 by performing a plasma nitridation on the metal-doped silicon oxide gate dielectric, to form nitridized metal-doped silicon oxide layer (SiONX). In one embodiment, one purpose of plasma nitridation after metal doping is to reduce or eliminate the crystallization of metal-doped silicon oxide (SiOX) layer at high temperature during a follow-up annealing process described below. The crystallization of SiOX could result in high gate leakage and degrade film quality of the gate dielectric. The plasma nitridation may be applied to other metal-doped silicon-containing gate dielectric if applicable in other examples.

A nitridation process (either a nitridation before or after the metal doping process) may be performed in a decoupling plasma chamber. In one embodiment, the nitridation process includes a nitrogen flow rate from about 200 to about 1500 sccm. In another embodiment, the nitridation process includes an effective RF power from about 50 to about 150 W (pulse mode). In another embodiment, the nitridation process includes a chamber pressure about 10 mTorr for a duration of about 10 to about 100 seconds. In a further embodiment, the nitridation process includes a temperature of less than about 100 degree C.

Still referring to FIGS. 1 and 2, the method proceeds to step 140 by performing an annealing process to the metal doped gate dielectric 210 after the metal doping process. The post annealing process incorporates metal dopants only within a surface portion of the gate dielectric for the purpose of work function tuning. In one example, the annealing process may include an annealing temperature ranging from about 700° C. to about 1100° C. The annealing process may include an annealing duration ranging from about 10 to about 300 seconds. Other methods such as rapid thermal annealing (RTA) may be additionally or alternatively used for the post annealing after the metal doping process.

Now referring to FIGS. 1 and 3, the method proceeds to step 150 by forming a gate electrode 230 on the gate dielectric 210. In one embodiment, a polysilicon layer is formed on the nitridized metal-doped silicon oxide layer (SiONX). The polysilicon layer may have a thickness from about 200 angstrom to about 3000 angstrom. The polysilicon is further doped with negative type (N-type) dopants or positive type (P-type) dopants. In one embodiment, the polysilicon layer is formed by low pressure chemical vapor deposition (LPCVD). The process to form the gate electrode may further include an etching step to pattern the deposited gate electrode material layer and form the gate electrode features. The gate dielectric 210 may be patterned with the gate electrode 230.

Other material may be additionally or collectively used for the gate electrode 230. Examples of the gate electrode include a metal gate and a fully silicidation (FUSI) gate. The FUSI gate electrode may include nickel silicide, cobalt silicide, tungsten silicide, tantalum silicide, titanium silicide, platinum silicide, erbium silicide, palladium silicide, or combinations thereof.

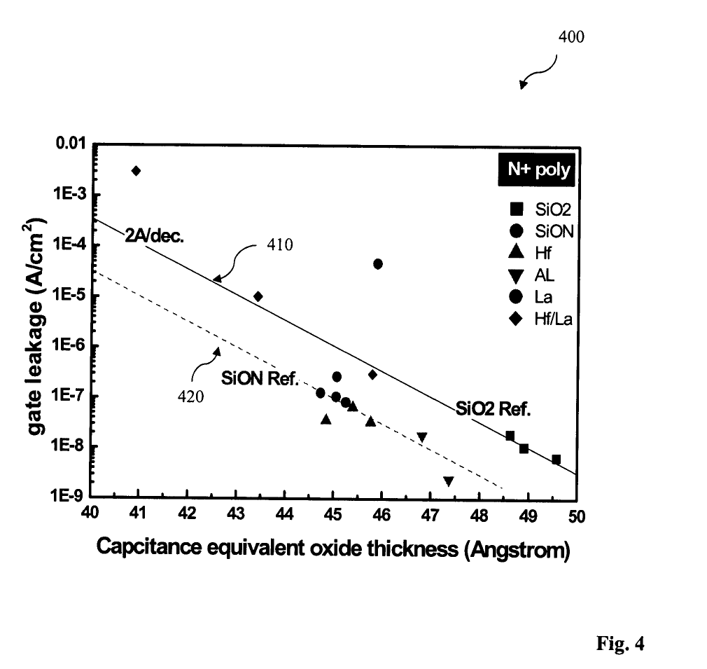

FIG. 4 is a diagram 400 of characteristics of gate leakage of metal doped gates in various embodiments according to aspects of the present disclosure. The diagram 400 illustrates capacitance equivalent oxide thickness versus gate leakage for exemplary gate dielectric doped with various metal dopants and N+ polysilicon gate electrode in various embodiments. A line 410 presents for a silicon oxide gate dielectric without doped metal and is used as a reference. Similarly, a line 420 is for a silicon oxynitride gate dielectric without doped metal and is used as another reference. Metal dopants include Hf, Al, La, or Hf/La in various examples. Test data for each metal doped gate dielectric and non-doped SiO₂ gate dielectric and SiON gate dielectric are present in the diagram 400 with different symbols as listed in the legend. The exemplary data show that the gate leakage is not degraded after performing the method to adjust work function according to aspects of the present disclosure.

The semiconductor device 200 and the method 100 may include other alternatives and extensions. In various embodiments, the gate electrodes may include a material selected from the group consisting of silicon-containing material, germanium-containing material, metal-containing material, and combinations thereof. For examples, the gate electrodes may include a material selected from the group consisting of poly-Si, poly-SiGe, metal, metal silicide, metal nitride, metal oxide, and combinations thereof.

The semiconductor device 200 may include other proper features and the method 100 may include other suitable processing steps to form other proper features as well. For example, gate spacers may be positioned on both sides of the gate stack formed by a process including deposition and etching. The gate spacers include a suitable dielectric material such as silicon nitride, silicon oxide, silicon carbide, silicon oxynitride, or combinations thereof. In another example, source and drain regions may be formed in the substrate using ion implantation or diffusion with proper dopants and disposed proximate to each end of the gate stack (the gate dielectric and gate electrode), respectively. In another example, various contacts/vias and multilayer interconnect features are formed on the substrate 210 and configured to properly connected to source region, drain region, gate electrode, other features in the substrate and/or the substrate itself. Certain isolation features may also be formed in and on the substrate. For examples, shallow trench isolation (STI) features may be formed in the substrate to separate various devices. Inter-level dielectric is disposed in the multilayer interconnects to isolate various interconnect features thereof.

It is understood that the semiconductor device is not limited to a specific transistor and may include negative metal oxide semiconductor transistor (NMOS), positive metal oxide semiconductor transistor (PMOS), complementary metal oxide semiconductor transistor (CMOS), a FINFET transistor, or combinations thereof. The semiconductor device may further include a bipolar transistor, a capacitor, a resistor, or combinations thereof.

The present invention achieves different advantages in various embodiments. For example, the present disclosed method provides simple and effective processing methods. The methods are compatible with current CMOS process. Furthermore, incorporating different metal species within the gate dielectric layer provides high process flexibility in tuning the work function. The method can be applied to regular dielectric constant (“k”), medium-k and high-k gate dielectric materials, respectively, for tuning the work function thereof. The method can be used with polysilicon gate electrode and FUSI gate electrode, and can also be used to other silicon-containing gate electrodes such as gate electrodes with silicon and metal present as compound or in multilayer structures. Furthermore, the present method could prevent metal species from diffusing into interface between the gate dielectric and substrate, eliminating leakage, mobility degradation and reliability degradation.

Thus, the present disclosure provide a method of fabricating a semiconductor device. The method includes forming a gate dielectric on a substrate; introducing metal dopants into the gate dielectric; annealing the gate dielectric; and forming a gate electrode on the gate dielectric.

In this method, the introducing metal dopants may include utilizing an ion-metal plasma process. The introducing metal dopants may include utilizing a process selected from the group consisting of ion-metal plasma process, plasma ion immersion implantation, ion implantation, and combinations thereof. In one embodiment, the introducing metal dopants may include introducing metal species selected from the group consisting of hafnium, aluminum, lanthanum, and combinations thereof. In another embodiment, the introducing metal dopants may include introducing metal species selected from the group consisting of Al, Ga, In, or combinations thereof to the gate dielectric having Al2O3 or Ga2O3. In another embodiment, the introducing metal dopants may include introducing metal species selected from the group consisting of Hf, La, Sc, Zr, Dy, Er, Lu, or combinations thereof to the gate dielectric having a high k material gate. In another embodiment, the introducing metal dopants may include introducing metal species selected from the group consisting of Ba, Sr, or combinations thereof to the gate dielectric for capacitor applications. In another embodiment, the introducing metal dopants may include introducing metal species selected from the group consisting of Y, Ti, V, Nb, Ta, Ce, Pr, Nd, Pm, Sm, Eu, Gd, Tb, Ho, Tm, Yb, or combinations thereof for other proper gate dielectric. The introducing metal dopants may include introducing the metal dopants into the gate dielectric with a depth less than about ¾ of a thickness of the gate dielectric. The introducing metal dopants may include introducing the metal dopants into the gate dielectric with a concentration ranging up to about 20 atomic %.

In the disclosed method, the forming a gate dielectric may include forming a silicon oxide gate dielectric. The forming a silicon oxide gate dielectric may utilize a process selected from the group consisting of thermal oxidation, rapid thermal process, and a combination thereof. The forming a gate dielectric may further include nitridizing the silicon oxide gate dielectric. The forming a gate dielectric may include forming the gate dielectric of a material selected from the group consisting of silicon oxide, silicon oxynitride, a dielectric of a high dielectric constant, and combinations thereof. In one embodiment, the forming of the gate electrode includes forming a silicon-containing gate electrode. For examples, the gate electrode includes a material selected from the group consisting of polysilicon, metal silicide, and combinations thereof. The annealing may include a temperature ranging from about 700° C. to about 1100° C. and a duration ranging from about 10 seconds to about 300 seconds.

The present disclosure also provides another embodiment of a method of fabricating a semiconductor device. The method includes forming a gate dielectric on a substrate; forming metal ions by a plasma process; incorporating the metal ions into the gate dielectric; and annealing the gate dielectric.

The disclosed method may further include nitridizing the gate dielectric; forming a gate electrode on the silicon oxide gate dielectric. In one embodiment, the forming metal ions may utilize a metal species selected from the group consisting of hafnium, aluminum, lanthanum, and combinations thereof.

The present disclosure also provides a semiconductor device in one embodiment. The method includes a gate dielectric disposed on a semiconductor substrate, wherein the gate dielectric includes metal dopants; and a silicon-containing gate electrode disposed on the gate dielectric.

In the disclosed semiconductor device, the metal dopants may be distributed in the gate dielectric with a depth less than about ¾ of a thickness of the gate dielectric. The metal dopants may be selected from the group consisting of Hf, Al, La, Al, Ga, In, Hf, La, Sc, Zr, Dy, Er, Lu, Ba, Sr, Y, Ti, V, Nb, Ta, Ce, Pr, Nd, Pm, Sm, Eu, Gd, Tb, Ho, Tm, Yb, and combinations thereof. The gate dielectric may include the metal dopants with a concentration in a range from near zero to about 20 atomic %. The gate dielectric may have a thickness ranging between about 5 angstrom and about 30 angstrom. The gate dielectric may include a material selected from the group consisting of silicon oxide, silicon oxynitride, a dielectric of a high dielectric constant, and combinations thereof. In one embodiment, the silicon-containing gate electrode may include polysilicon. The substrate may include silicon.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

1. A method of fabricating a semiconductor device comprising:
forming a gate dielectric on a substrate;
introducing metal dopants into the gate dielectric;
annealing the gate dielectric; and
forming a gate electrode on the gate dielectric.

2. The method of claim 1, wherein the introducing metal dopants comprises utilizing an ion-metal plasma process.

3. The method of claim 1, wherein the introducing metal dopants comprises utilizing a process selected from the group consisting of ion-metal plasma process, plasma ion immersion implantation, ion implantation, and combinations thereof.

4. The method of claim 1, wherein the introducing metal dopants comprises introducing metal species selected from the group consisting of hafnium, aluminum, lanthanum, and combinations thereof.

5. The method of claim 1, wherein the introducing metal dopants comprises introducing metal species selected from the group consisting of Al, Ga, In, Hf, La, Sc, Zr, Dy, Er, Lu, Ba, Sr, Y, Ti, V, Nb, Ta, Ce, Pr, Nd, Pm, Sm, Eu, Gd, Tb, Ho, Tm, Yb, or combinations thereof.

6. The method of claim 1, wherein the introducing metal dopants comprises introducing the metal dopants into the gate dielectric with a depth less than about ¾ of a thickness of the gate dielectric.

7. The method of claim 1, wherein the introducing metal dopants comprises introducing the metal dopants into the gate dielectric with a concentration ranging up to about 20 atomic %.

8. The method of claim 1, wherein the forming a gate dielectric comprises forming a silicon oxide gate dielectric.

9. The method of claim 8, wherein the forming a silicon oxide gate dielectric comprises utilizing a process selected from the group consisting of thermal oxidation, rapid thermal process, and a combination thereof.

10. The method of claim 7, wherein the forming a gate dielectric further comprises nitridizing the silicon oxide gate dielectric.

11. The method of claim 1, wherein the forming a gate dielectric comprises forming the gate dielectric of a material selected from the group consisting of silicon oxide, silicon oxynitride, a dielectric of a high dielectric constant, and combinations thereof.

12. The method of claim 1, wherein the annealing comprises an annealing temperature ranging from about 700° C. to about 1100° C. and a duration ranging from about 10 seconds to about 300 seconds.

13. The method of claim 1, wherein the forming a gate electrode comprises forming a gate electrode having a material selected from the group consisting of a silicon-containing material, a fully silicidation (FUSI) material, metal, and combinations thereof.

14. A method of fabricating a semiconductor device comprising:
forming a gate dielectric on a substrate;
forming metal ions by a plasma process;
incorporating the metal ions into the gate dielectric; and
annealing the gate dielectric.

15. The method of claim 14 further comprising:
nitridizing the gate dielectric;
forming a gate electrode on the silicon oxide gate dielectric.

16. A semiconductor device comprising:
a gate dielectric disposed on a semiconductor substrate, wherein the gate dielectric includes metal dopants; and
a silicon-containing gate electrode disposed on the gate dielectric.

17. The semiconductor device of claim 16, wherein the metal dopants are distributed in the gate dielectric with a depth less than about ¾ of a thickness of the gate dielectric.

18. The semiconductor device of claim 16, wherein the metal dopants are selected from the group consisting of Hf, Al, La, Al, Ga, In, Hf, La, Sc, Zr, Dy, Er, Lu, Ba, Sr, Y, Ti, V, Nb, Ta, Ce, Pr, Nd, Pm, Sm, Eu, Gd, Tb, Ho, Tm, Yb, and combinations thereof.

19. The semiconductor device of claim 16, wherein the gate dielectric comprises the metal dopants with a concentration in a range from near zero to about 20 atomic %.

20. The semiconductor device of claim 16, wherein the gate dielectric has a thickness ranging between about 5 angstrom and about 30 angstrom.

21. The semiconductor device of claim 16, wherein the gate dielectric comprises a material selected from the group consisting of silicon oxide, silicon oxynitride, a dielectric of a high dielectric constant, and combinations thereof.

22. The semiconductor device of claim 16, wherein the silicon-containing gate electrode is polysilicon.
